(19) United States
(12) Patent Application Publication
(10) Pub. No.: US 2013/0118408 A1
(43) Pub. Date: May 16, 2013

(54) SYSTEM FOR USE IN THE FORMATION OF SEMICONDUCTOR CRYSTALLINE MATERIALS

(71) Applicants: Jean-Pierre Faurie, Valbonne (FR); Bernard Beaumont, Le Tignet (FR)

(72) Inventors: Jean-Pierre Faurie, Valbonne (FR); Bernard Beaumont, Le Tignet (FR)

(73) Assignee: SAINT-GOBAIN CERAMICS & PLASTICS, INC., Worcester, MA (US)

(21) Appl. No.: 13/673,105

(22) Filed: Nov. 9, 2012

Related U.S. Application Data
(60) Provisional application No. 61/558,117, filed on Nov. 10, 2011.

(51) Int. Cl. C30B 25/08; C30B 25/14

(52) U.S. Cl. CPC C30B 25/08; C30B 25/14
USPC 118/726

(57) ABSTRACT

A system used in the formation of a semiconductor crystalline material includes a first chamber configured to contain a liquid metal and a second chamber in fluid communication with the first chamber, the second chamber having a greater volume than a volume of the first reservoir chamber. The system further includes a vapor delivery conduit coupled to the first chamber configured to deliver a vapor phase reactant material into the first chamber to react with the liquid metal and form a metal halide vapor phase product.

### BACKGROUND

1. Field of the Disclosure

The following is directed to a system used in the formation of semiconductor crystalline materials, and particularly formation and delivery of chemical compositions for epitaxial formation of semiconductor materials.

2. Description of the Related Art

The semiconductor industry is very dependent upon sources of ultrahigh purity reagents. Other industries also have high purity requirements, but few compare with the purity requirements in the semiconductor industry. Liquid vapor delivery systems are used in a number of manufacturing processes. For example, liquid vapor delivery systems are used in the manufacture of optical wave-guides.

In certain industries, in the formation of semiconductor films and devices, it is known to provide semiconductor devices by reacting a silicon wafer, appropriately prepared with the semiconductor component pattern thereon, with the vapor from chemical liquid vapor source materials or dopants. Examples of common chemical vapor source materials are boron tribromide, phosphorous oxychloride, phosphorous tribromide, silicon tetrachloride, dichlorosilane, silicon tetrabromide, arsenic trichloride, arsenic tribromide, antimony pentachloride and various combinations of these. In the compound semiconductor industry, epitaxial III V semiconductor films are commonly grown by metalorganic chemical vapor deposition (MOCVD) using liquid vapor source materials such as trimethylgallium, triethylgallium, trimethylaluminum, ethyldimethylindium, tertiary-butylarsine, tertiary-butylphosphine, and other liquid sources. Some II VI compound semiconductor films are also fabricated using liquid sources. However, due to the concerns of the toxicity with many of these materials, the industry is making efforts to reduce the amount of these materials present within the manufacturing environment, and particularly reducing the size of vessels holding the toxic materials to reduce the potential for danger.

### SUMMARY

According to one aspect, a system used in the formation of a semiconductor crystalline material includes a first chamber configured to contain a liquid metal, a second chamber in fluid communication with the first chamber, the second chamber having a greater surface area than a surface area of the first reservoir chamber, and a vapor delivery conduit coupled to the first chamber configured to deliver a vapor phase reactant material into the first chamber to react with the liquid metal and form a metal halide vapor phase product.

According to another aspect, a system used in the formation of a semiconductor crystalline material includes a first chamber configured to contain a liquid metal, a second chamber in fluid communication with the first chamber, the second chamber having a greater surface area than a surface area of the first chamber, and a vapor delivery conduit comprising a bubbler at least partially contained within the first chamber and submerged within the liquid metal configured to deliver a vapor phase reactant material into the liquid metal and form a metal halide vapor phase product.

According to yet another aspect, a system used in the formation of a semiconductor crystalline material includes a first chamber comprising a temperature sufficient to maintain liquid gallium, a second chamber in fluid communication with the first chamber and configured to contain a greater volume of liquid metal than a volume of liquid metal within the first chamber and replenish the liquid metal within the first chamber during operation, wherein the second chamber is external to a growth chamber, and a vapor delivery conduit comprising a bubbler at least partially contained within the first chamber and submerged within the liquid metal configured to deliver a vapor phase reactant material into the liquid metal and form a metal halide vapor phase product.

### BRIEF DESCRIPTION OF THE DRAWINGS

The present disclosure may be better understood, and its numerous features and advantages made apparent to those skilled in the art by referencing the accompanying drawings.

FIG. 1 includes a schematic of a system used in the formation of a semiconductor crystalline material in accordance with an embodiment.

FIG. 2 includes a schematic of a system used in a formation of a semiconductor crystalline material in accordance with an embodiment.

FIG. 3 includes a cross-sectional diagram of a semiconductor crystalline material formed using the system described in an embodiment.

FIG. 4 includes a schematic of a system used in the formation of a semiconductor crystalline material in accordance with an embodiment.

The use of the same reference symbols in different drawings indicates similar or identical items.

### DETAILED DESCRIPTION

The following is generally directed to a system used in the formation of semiconductor crystalline materials. More particularly, the following is directed to a system for controlling the combination of reactance materials used in the formation of semiconductor crystalline materials. Additionally, the systems described in the embodiments herein further facilitate controlled delivery of a chemical products formed through chemical reaction between chemical reactants, wherein the chemical products can be delivered to a controlled growth environment to facilitate the formation of semiconductor crystalline materials. Moreover, the systems of the following embodiments can be used to facilitate long duration growth of semiconductor crystalline materials, including for example, growth operations lasting hours, or even days, facilitating the formation of exceptionally thick semiconductor crystalline layers and even boules of semiconductor crystalline materials.

Semiconductor crystalline materials herein include Group III-V compositions, including crystalline materials of Group III-nitride compositions. Such materials have been recognized as having great potential for short wavelength emission, and thus suitable for use in the manufacturing of light emitting diodes (LEDs), laser diodes (LDs), UV detectors, and high-temperature electronics devices. It will be appreciated that Group III materials is reference to elements in Group III of the Periodic Table of Elements, which includes B, Al, Ga, In, Tl, and may further be defined as containing post-transition elements of Al, Ga, In, and Tl. Semiconductor crystalline materials can include semiconductor compounds including ternary compounds, such as, indium gallium nitride (InGaN) and gallium aluminum nitride (GaAlN), and even the quaternary compounds (AlGaInN) are direct band gap semiconductors.

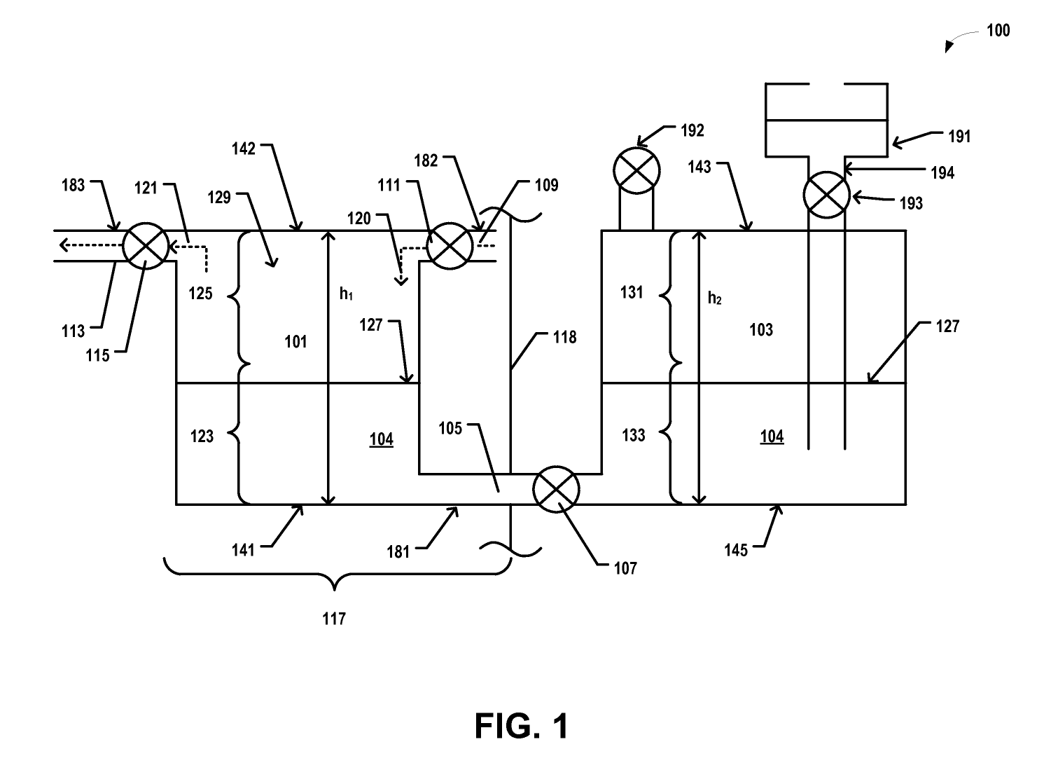

FIG. 1 includes a schematic of a system used in the formation of semiconductor crystalline materials in accordance with an embodiment. In particular, the system 100 can be used in the preparation and delivery of chemical compounds and products used in extended growth operations to form particular semiconductor crystalline material structures. The system 100 can include a first chamber 101 that can contain a liquid metal material 104. As further illustrated, the system 100 can include a second chamber 103 that can be in fluid communication with the first chamber 101. As further illustrated, the second chamber 103 can be configured to contain a content of the liquid metal material 104. In one embodiment, the first chamber 101 can be coupled to the second chamber 103 via a reservoir conduit 105. Accordingly, the liquid metal 104 can flow between the first chamber 101 and the second chamber 103.

The liquid metal 104 can include one or more transition metal elements. For example, certain suitable transition materials can include gallium. In fact, the liquid metal 104 can consist essentially of liquid gallium, such that it is essentially 99.999% pure liquid gallium.

As further illustrated, and in accordance with an embodiment, the system 100 can include a valve 107 within the reservoir conduit 105 between the first chamber 101 and the second chamber 103. The valve 107 can be used to control the flow of liquid metal 104 between the first chamber 101 and the second chamber 103.

As noted above, the liquid metal 104 can flow between the second chamber 103 and the first chamber 101. More particularly, in accordance with an embodiment, the second chamber 103 may contain a content of the liquid metal 104 and may be utilized to recharge the volume of liquid metal 104 within the first chamber 101 during extended growth operations.

According to another embodiment, the second chamber 103 can have a greater volume than the volume of the first chamber 101 thus facilitating recharging of the volume of liquid metal within the first chamber 101 during extended growth operations. For example, the second chamber 103 can have a volume that is at least 10 times greater than a volume of the first chamber 101, as measured by the equation (V2/V1) wherein V2 is the volume of the second chamber 103 and V1 is the volume of the first chamber 101. In another embodiment, the second chamber can have a volume that is at least about 20 times greater, at least about 50 times greater, or even at least about 100 times greater than the volume of the first chamber 101. Still, the second chamber can have a volume that is not greater than about 1000 times, such as not greater than about 800 times, or not greater than about 500 times the volume of the first chamber 101. It will be appreciated that the first chamber 101 and second chamber 103 can have a difference in volume within a range between any of the minimum and maximum ratios noted above.

The first chamber 101 can have a volume of at least about 200 cubic centimeters (cc), such as at least about 250 cc, at least about 500 cc, at least about 1000 cc, at least about 2000 cc, at least about 3000 cc,. Still, in certain embodiments, the first chamber 101 can have a volume of not greater than about 5000 cc, such as not greater than about 4000 cc or not greater than about 3500 cc. It will be appreciated that the volume of the first chamber 101 can be within a range between any of the minimum and maximum values noted above.

The second chamber 103 can include a volume of at least about 2000 cc, such as at least about 3000 cc, at least about 5000 cc, at least about 10,000 cc, or even at least about 20,000 cc, at least about 30,000 cc. Still, in one particular embodiment, the second chamber 103 can have a volume of not greater than about 55,000 cc, such as not greater than about 50,000 cc or not greater than about 45,000 cc. It will be appreciated that the second chamber 103 can have a volume within a range between any of the minimum and maximum values noted above.

In accordance with another embodiment, the surface area of the first chamber 101 and the second chamber 103 can have a particular ratio relative to each other to facilitate extended growth operations and proper interactions between reactant materials during extended growth operations. For example, the second chamber 103 can have a surface area that is at least 2 times greater than the surface area of the first chamber 101, as measured by the equation (SA2/SA1) wherein SA2 is the surface area of the second chamber 103 and SA1 is the surface area of the first chamber 101. It will be appreciated that reference to the surface area of the first chamber 101 or second chamber 103, is a measure of the surface area of the interior of the chambers. In another embodiment, the second chamber can have a surface area that is at least about 4 times greater, at least about 6 times greater, at least about 8 times greater, or even at least about 10 times greater than the surface area of the first chamber 101. Still, the second chamber can have a surface area that is not greater than about 1000 times, such as not greater than about 800 times, not greater than about 500 times, not greater than about 200 times, not greater than about 100 times the surface area of the first chamber 101. It will be appreciated that the first chamber 101 and second chamber 103 can have a ratio of surface area within a range between any of the minimum and maximum ratios noted above.

In particular instances, the first chamber 101 can have a particular surface area, which can be a measure of the total interior surface area of the chamber and can facilitate proper and continuous reaction between reactant materials during extended growth operations. For example, in certain embodiments, the first chamber 101 can have a surface area of at least about 80 cm², such as at least about 100 cm², at least about 120 cm², at least about 180 cm², at least about 200 cm², or even at least about 250 cm². Still, in certain embodiments, the first chamber 101 can have a surface area of not greater than about 2000 cm², such as not greater than about 1500 cm² or not greater than about 800 cm². It will be appreciated that the surface area of the first chamber 101 can be within a range between any of the minimum and maximum values noted above.

In accordance with an embodiment, the reservoir conduit 105 can be coupled to the first chamber 101 at a particular location. For example, the first chamber 101 can be defined by a height (h₁) as illustrated in FIG. 1. Furthermore, the first chamber 101 can have an upper half 125 defined between the upper surface 142 of the first chamber 101 and a midpoint of the height (h₁), and a lower half 123 defined as a region between the lower surface 141 and half of the height of the first chamber 101. As illustrated, the reservoir conduit 105 can be coupled to the first chamber 101 within the lower half of the first chamber 101. More particularly, the reservoir conduit 105 can be coupled to the first chamber 101 at a lowest point of the first chamber 101, and particularly coupled to the lower surface 141 of the first chamber 101, such that the reservoir conduit 105 intersects the lower surface 141, or even is coextensive with and defines a portion of the lower surface 141.

In certain instances, the system 100 can be formed such that the reservoir conduit 105 is coupled to the second chamber 103 in a particular position. As illustrated, the second chamber 103 can have a height (h₂) that defines an upper half between an upper surface 143 and a midpoint of the height (h₂), and a lower half 133 between a lower surface 145 and a midpoint of the height (h₂). As illustrated, and in accordance with an embodiment, the reservoir conduit 105 can be coupled to the second chamber 103 in the lower half 133 of the second chamber 103. More particularly, the reservoir conduit 105 can be coupled to the second chamber 103 at a position abutting the lower surface 145, such that it is coextensive with the lower surface 145. In one particular embodiment, the lower surface 145, lower surface 181 of the reservoir conduit 105, and lower surface 141 can be coextensive, such that they extend along and define a same, single plane. Such designs described in the embodiments herein can facilitate easy of flow and complete recharging of the liquid metal 104 from the second chamber 103 and the first chamber 101 during extended growth operations.

In accordance with an embodiment, the first chamber 101 can be made of an inorganic material. Notably, the inorganic material may be particularly suitable for containing the liquid metal 104 without causing contamination to the material of the liquid metal 104. In one particular embodiment, the inorganic material may include an oxide material, and more particularly can include a silica material. In one embodiment, the first chamber 101 can be formed of quartz, and more particularly may consist essentially of quartz.

In accordance with another embodiment, the second chamber 103 can be made of an inorganic material. Notably, the inorganic material may be suitable for containing liquid metal 104, and particularly holding the liquid metal 104 without contaminating the material, such that it is chemically inert to the composition of the liquid metal 104. In accordance with one particular embodiment, the second chamber 103 can include an oxide material, and more particularly silica, and yet more particularly quartz. In accordance with one particular embodiment the second chamber 103 can consist essentially of quartz.

Furthermore, it will appreciated that other components utilized in the system 100 can be made of an inorganic material, and more particularly the same inorganic material of the first chamber 101 or second chamber 103. For example, all material components of the system, including for example, conduit and valve components, can include an oxide material, may further include silica, and more particularly, can be essentially of quartz.

In accordance with an embodiment, the system 100 can include a vapor delivery conduit 109 coupled to the first chamber 101. The vapor delivery conduit 109 can be configured to deliver a vapor phase reactant material 120 into the first chamber 101 to react with the liquid metal 104 and form a chemical product. The chemical product can be a metal halide vapor phase product 121. The vapor delivery conduit 109 can be formed of an inorganic material, more particularly silica, such as quartz, and more particularly may consist of essentially quartz.

As further illustrated, a valve 111 may be placed within the vapor delivery conduit 109 to facilitate controlled delivery of the vapor phase reactant material 120 to the first chamber 101.

In accordance with an embodiment, the vapor delivery conduit 109 can be a blower configured to deliver a stream of the vapor phase reactant material 120 to the first chamber 101, and more particularly a stream of the vapor phase reactant material 120 over the upper surface 127 of the liquid metal 104. The blower can be positioned in a particular region of the first chamber 101 to facilitate effective operation. For example, the blower can be coupled to the first chamber 101 in the upper half 125 of the first chamber 101. More particularly, the blower, or the vapor delivery conduit 109, can be couple to the first chamber 101 at the upper surface 142 such that it is in direct contact with the upper surface 142, and more particularly, such that an upper surface 182 of the vapor delivery conduit 109 is abutting and coextensive with the upper surface 142 of the first chamber 101. For example, as illustrated, the upper surface 182 and the upper surface 142 can extend along and define a same plane.

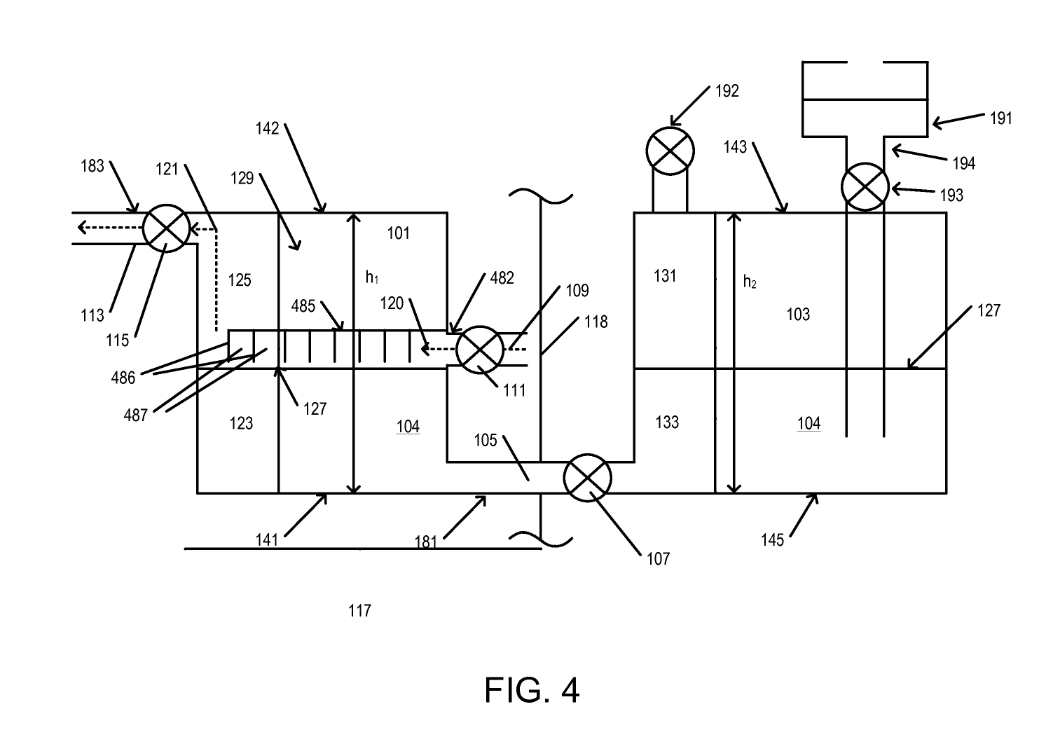

Still, according to another embodiment, as illustrated in FIG. 4, the vapor delivery conduit 109 can be shifted downward relative to the upper surface 142, such that the upper surface 482 can be laterally shifted away from the upper surface 142, and thus surfaces 482 and 142 may be oriented in a non-coextensive manner relative to each other. As illustrated, the upper surface 482 of the vapor delivery conduit 109 may be oriented approximate to the midpoint of the first chamber 101, and thus connected to the first chamber 101 near the midpoint relative to the height. More particularly, the orientation of the vapor delivery conduit 109 of FIG. 4 can be proximate to the upper surface 127 of the liquid metal 104. For example, the vapor delivery conduit 109 can be oriented such that the upper surface 127 of the liquid metal 104 is not spaced apart from the upper surface 482 by a distance of greater than about half of the total height (h₁) of the first chamber 101. Such orientation can facilitate proper gas flow mechanics and reaction between the vapor phase reactant material 120 and the liquid metal 104.

Additionally, a vapor control device 485 can be placed in the first chamber 101 to facilitate control of the residence time of the vapor phase reactant material 120 over the liquid metal 104. For example, the vapor control device 485 can have baffles 486, which can be in the form of walls, vanes, chicanes, or the like, and which define channels 486 between the baffles 486 for control of the direction of flow of the vapor phase reactant material 120. The baffles 486 can be arranged to define a tortuous pathway through which the vapor phase reactant material 120 can flow, wherein the tortuous pathway increases the duration of time in which the vapor phase reactant material 120 can be in contact with the liquid metal 104, facilitating improved reaction efficiency between the vapor phase reactant material 120 and the liquid metal 104. The vapor control device 485 can be placed in the first chamber 101 proximate to the vapor delivery conduit 109, and may be attached to any of the interior surfaces or walls of the first chamber 101.

In accordance with an embodiment, the vapor phase reactant material 120 can include a halide material, and more particularly a vaporous halide compound. Certain suitable halide materials can include hydrogen. For example, in one embodiment, the vapor phase reactant material 120 can include hydrogen chloride (HCl). In one particular embodiment, the vapor phase reactant material 120 consists essentially of hydrogen chloride.

The first chamber 101 can have a particular to facilitate maintaining the liquid metal 104 in a liquid state. For example, the temperature of the first chamber 101 can be at least about 40° C., at least about 100° C., at least about 200° C., at least about 500° C., or even at least about 800° C. Still the temperature of the first chamber 101 may be not greater than about 2000° C., such as not greater than about 1800° C. or even not greater than about 1500° C. It will be appreciated that the temperature within the first chamber 101 can be within a range between any of the minimum or maximum values noted above.

Furthermore, in certain instances, the temperature of the second chamber 103 can be significantly less than (i.e., greater than about 50% difference) as the temperature within the first chamber 101. For example, the temperature of the second chamber 103 may be not greater than about 2000° C., such as not greater than about 1800° C., not greater than about 1500° C., not greater than about 1000° C., not greater than about 800° C., not greater than about 500° C., not greater than about 200° C., or even not greater than about 150° C. In other instances, the second chamber 103 can be at a temperature of at least about 40° C., at least about 60° C., at least about 70° C., at least about 80° C., or even at least about 100° C. It will be appreciated that the temperature within the second chamber 103 can be within a range between any of the minimum or maximum values noted above.

According to another embodiment, the first chamber 101 can have a particular pressure to facilitate containment of the reactant materials in the proper phases. For example, the pressure in the first chamber 101 can be at least about 0.01 atm, such as at least about 0.05 atm, or even at least about 0.1 atm. In another embodiment, the pressure within the first chamber can be not greater than about 2 atm, such as not greater than about 1.5 atm, not greater than about 1 atm, not greater than about 0.8 atm, or even not greater than about 0.5 atm. It will be appreciated that the pressure within the first chamber 101 can be within a range between any of the minimum or maximum values noted above.

Furthermore, in one embodiment, the pressure within the second chamber 103 can be substantially the same as, or exactly the same as the pressure within the first chamber 101. However, in certain embodiments, the pressure within the second chamber 103 can be greater than a pressure within the first chamber 101, facilitating controlled delivery of the liquid metal 104 from the second chamber 103 to the first chamber 101 during operation. In certain instances, the pressure within the second chamber 103 can be at least about 1% greater, at least about 2% greater, or even at least about 3% greater than the pressure within the first chamber 101.

As further illustrated in FIG. 1, the system 100 can include an exit conduit 113 coupled to the first chamber 101, and configured to deliver a metal halide vapor phase product 121 from the first chamber 101 and to a growth chamber containing a substrate assembly configured to grow a semiconductor crystalline material. The metal halide vapor phase product 121 is the result of a chemical reaction between the vapor phase reactant material 120 and the liquid metal 104. In accordance with an embodiment, the exit conduit 113 can be coupled to the first chamber 101 at a particular location, including for example the upper half 125 of the first chamber 101 such that it is maintained above the upper surface 127 of the liquid metal 104. In accordance with an embodiment, the exit conduit 113 can be coupled to the upper surface 142 of the first chamber 101, and more particularly, an upper surface 183 of the exit conduit 113 is abutting and coextensive with the upper surface 142 of the first chamber 101. For example, as illustrated, the upper surface 183 of the exit conduit 113 and the upper surface 142 of the first chamber 101 can extend along and define a same plane.

As further illustrated, the system 100 can be formed such that a valve 115 is inserted within the exit conduit 113. The valve 115 can be used to control the flow of the metal halide vapor phase product from the first chamber 101 into a growth chamber to a surface configured for the formation of a semiconductor crystalline material.

In accordance with an embodiment, the metal halide vapor phase product can include gallium. Another embodiment, the metal halide vapor phase product can also include chlorine, such that the metal halide vapor phase product may include gallium chloride, and more particularly can consist essentially of gallium chloride.

In another embodiment, the metal halide vapor phase product can include a second vapor phase product in addition to the product comprising gallium chloride. The second vapor phase product can include for example, hydrogen, and may consist essentially of a hydrogen molecule (H₂).

As further illustrated in FIG. 1, the system 100 can include separation of the first chamber 101 from the second chamber 103. For example, in one particular embodiment, the first chamber 101 can be contained within a growth chamber 117, wherein the growth chamber wall 118 separates and extends between the first chamber 101 and the second chamber 103. Accordingly, in certain embodiments, the second chamber 103 can be external to the growth chamber 117. As will also be appreciated, in order to control the reaction within the first chamber 101, the valve 107 of the reservoir conduit 105 can be external to the growth chamber 117 and positioned on the same side of the growth chamber wall 118 as the second chamber 103. Furthermore, a portion of the vapor delivery conduit 109 may extend external to the growth chamber 117 and through the growth chamber wall 118. While not illustrated, it will be appreciated, that in certain instances, the valve 111 may be external to the growth chamber 117 and thus be on the same side of the growth chamber wall 118 as the second chamber 103. Such a design may facilitate external control of vapor phase reactant material to the first chamber 101.

According to an embodiment, the system 100 can further include a recharge reservoir 191 coupled to the second chamber 103, and particularly, in fluid communication with the second chamber 103 and configured to deliver liquid metal to the second chamber 103. The system 100 can further including a valve 193 for control of the flow of liquid metal 104 between the recharge reservoir 191 and the second chamber 103. For example, during extended growth operations, the valve 193 can be opened facilitating liquid metal contained in the recharge reservoir 191 to flow into the second chamber 103 increasing the volume of liquid metal in the second chamber 103 and thus also increasing the volume of liquid metal available to be delivered into the first chamber 101.

In particular instances, at least a portion of the recharge reservoir can be flexible. In one embodiment, the recharge reservoir 191, and particularly the extension 194 can be made of an organic material, such as a polymer, and more particularly polytetrafluoroethylene (PTFE). Use of a flexible material may be particularly suitable because of pressure differences between the second chamber 103 and the recharge reservoir 191.

The system 100 can further include a primer valve 192 coupled to the second chamber 103, which can facilitate control of the pressure within the second chamber 103. The primer valve 192 may facilitate control of the pressure within the second chamber 103, and more particularly, control of the pressure difference between the second chamber 103 and the first chamber 101 to facilitate recharging of liquid metal 104 from the second chamber 103 to the first chamber 101 during extended growth operations.

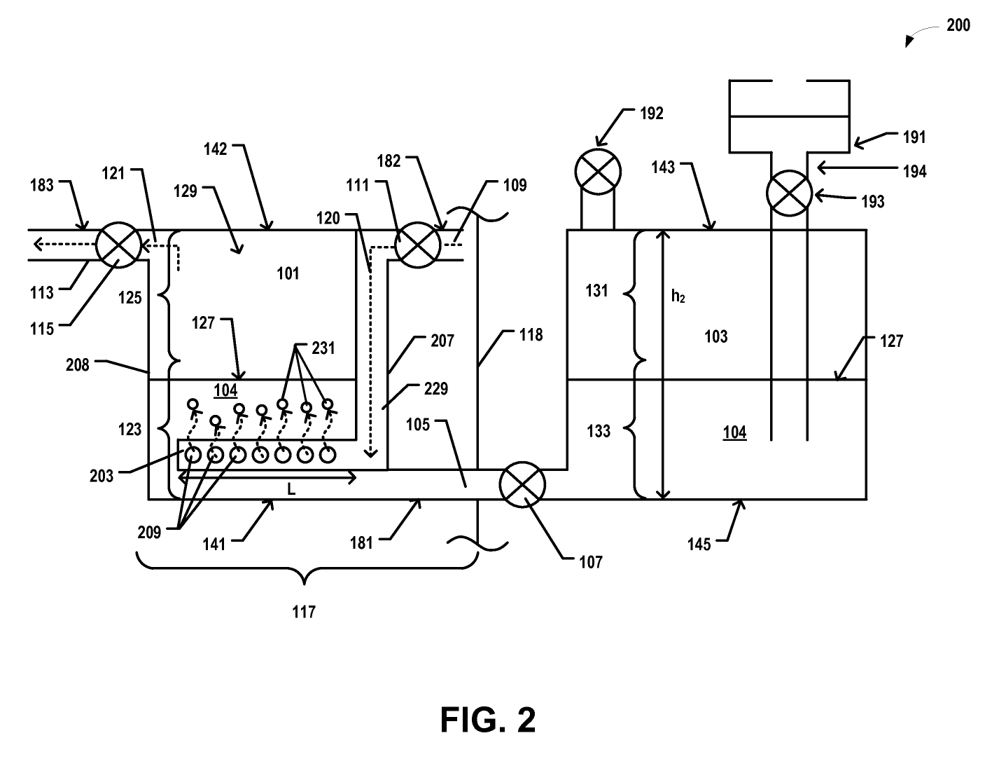

FIG. 2 includes a schematic of a system using the formation of a semiconductor crystalline material in accordance with an embodiment. As illustrated, the system 200 can incorporate some of the same features as the system 100 of FIG. 1. For example, the system 200 can include a first chamber 101 configured to contain a liquid metal 104 and further including a vapor delivery conduit 109 and exit conduit 113. As further illustrated, the system 200 can include a second chamber 103 configured to contain a liquid metal 104, wherein the second chamber 103 can be in fluid communication with the first chamber 101 via a reservoir conduit 105 configured to deliver the liquid metal between the second chamber 103 and the first chamber 101.

As further illustrated, the system 200 can include a vapor delivery conduit 109 in the form of a bubbler 229. The bubbler 229 can include a submerged portion 203 that is disposed beneath the upper surface 127 of the liquid metal 104. As such, the submerged portion 203 of the bubbler 229 can be configured to deliver the vapor phase reactant material 120 into the volume of the liquid metal 104, below the surface 127 of the liquid metal 104, and causing bubbles 231 of the vapor phase reactant material 120 to be disposed into the liquid metal 104. Delivery of the vapor phase reactant material 120 through the bubbler 229 facilitates a chemical reaction between the vapor phase reactant material 120 and the liquid metal 104 resulting in the metal halide vapor phase product 121 that can exit the first chamber 101 through the exit conduit 113.

In accordance with an embodiment, the submerged portion 203 of the bubbler 229 can be partially submerged within the liquid metal 104 within the first chamber 101. More particularly, the submerged portion 203 may include a cylindrical contour having a length (L) extending outward from a first wall 207 of the first chamber 101 and into the volume of the first chamber 101 toward a second wall 208 of the first chamber 101 opposite the first wall 207. Furthermore, in accordance with an embodiment, the submerged portion 203 of the bubbler 229 can include a plurality of openings 209 extending along the length (L) of the submerged portion 203. It will be appreciated that the plurality of openings 209 can be configured to deliver the vapor phase reactant material 120 into the liquid metal 104 and facilitate the formation of bubbles 231.

For certain designs, the length (L) of the submerged portion 203 can be at least about 1 cm, at least about 2 cm, or even at least about 3 cm to facilitate proper reaction dynamics. In other instances, the length (L) of the submerged portion 203 can be not greater than about 12 cm, such as not greater than about 10 cm, or even not greater than about 8 cm. It will be appreciated that the length (L) of the submerged portion 203 can be within a range between any of the minimum and maximum values noted above.

In accordance with an embodiment, the submerged portion 203 of the bubbler 229 can be configured to extend from the first wall 207 of the first chamber 101 in a lower half of the first chamber 101. Notably, the position of the submerged portion 203 may be significant to ensure delivery of the vapor phase reactant material 120 below the upper surface 127 of the liquid metal 104. Furthermore, the position of the submerged portion 203 within the first chamber 101 can facilitate extended growth operations wherein the submerged portion 203 is positioned sufficiently low enough below the level 127 of the liquid metal 104 to facilitate extended durations of growth of semiconductor crystalline material within the growth chamber.

According to a particular embodiment, the submerged portion 203 of the bubbler 229 can have a plurality of openings 209 facilitating the formation of bubbles and a chemical reaction. In particular instances, the plurality of openings 209 can have substantially the same size. Notably, the size of the openings can be within a range between about 0.1 mm² and about 10 mm², and more particularly within a range between about 0.8 mm² and about 5 mm².

In an alternative embodiment, the submerged portion 203 of the bubbler 229 can be formed of a sintered quartz tube comprising a plurality of micro-openings. The micro-openings can be significantly more numerous than the openings 209 described in other embodiments herein, and may further have an average area that is significant less than about 0.1 mm². For example, the openings can be less than about 80 microns², less than about 50 microns², less than about 30 microns², or even less than about 10 microns².

For certain designs, the diameter of one or more conduits (e.g., the reservoir conduit 105) can be at least about 1 mm, at least about 2 mm, or even at least about 3 mm to facilitate proper operation of the system. In other instances, the diameter of one or more conduits can be not greater than about 20 mm, such as not greater than about 15 mm, or even not greater than about 10 mm. It will be appreciated that the diameter of one or more of the conduits can be within a range between any of the minimum and maximum values noted above.

The systems described herein can be operated to deliver a particular content of source material (i.e., vapor phase reactant material) to facilitate extended growth durations. For example, the source material can be delivered at rates of at least about 100 cc/min, such as at least about 200 cc/min, at least about 300 cc/min, or even at least about 400 cc/min. Still, according to one embodiment, the source material can be delivered at a rate of not greater than about 5000 cc/min, such as not greater than about 4000 cc/min, or even not greater than about 3000 cc/min. It will be appreciated that the delivery rate of source materials can be within a range between any of the minimum and maximum values noted above.

It will be appreciated that the systems described herein can be used to facilitate the formation of a metal halide vapor phase product which can be delivered to a particular place within a growth chamber and facilitate the formation of a semiconductor crystalline material. Notably, the systems herein may be used to facilitate growth of semiconductor crystalline material through processes such as epitaxy, including for example, hydride vapor phase epitaxy (HVPE).

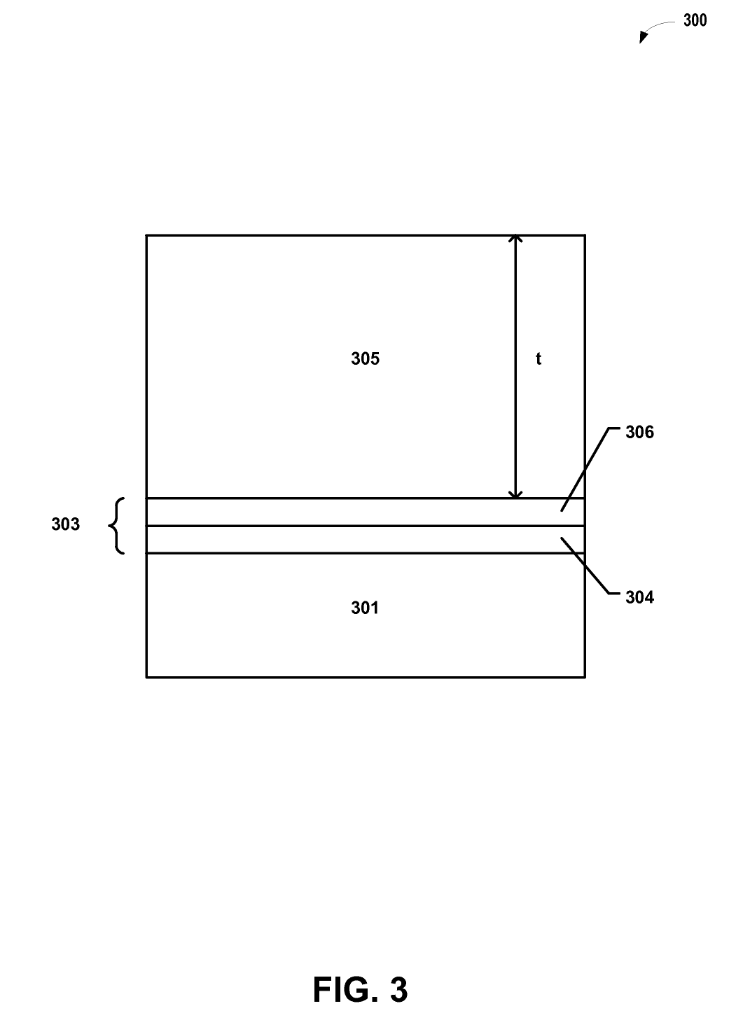

Suitable semiconductor crystalline materials can include a Group III-V nitride semiconductor material. FIG. 3 includes a cross-sectional view of an exemplary semiconductor article 300, including a substrate 301 and a buffer layer 303 overlying the substrate 301. In particular, the buffer layer 303 can overlie an upper major surface of the substrate 301, and more particularly, the buffer layer 303 can be in direct contact with upper major surface of the substrate 301.

Forming the buffer layer 303 can include a deposition process. For example, the buffer layer 303 can be deposited on an upper major surface of the substrate 301 within a reaction chamber. According to one process, the substrate can be loaded into a reaction chamber, and after providing a suitable environment within the reaction chamber, a buffer layer can be deposited on the substrate. According to one embodiment, a suitable deposition technique can include chemical vapor deposition. In one particular instance, the deposition process can include metal-organic chemical vapor deposition (MOCVD).

The buffer layer 303 may be formed from a plurality of films. For example, as illustrated in FIG. 3, the buffer layer 303 can include a film 304 and a film 306. In accordance with an embodiment, at least one of the films, can include a crystalline material. In more particular instances, the film 304, which can be in direct contact with the surface of the substrate 301, can include silicon, and may consist essentially of silicon. The film 304 may facilitate separation between the substrate 301 and semiconductive layers overlying the film 304 as described herein.

As illustrated in FIG. 3, the film 306 can overly, and more particularly, can be in direct contact with the film 304. The film 306 can have suitable crystallographic features for epitaxial formation of layers thereon. Notably, in one embodiment the film 304 can include a semiconductive material. Suitable semiconductive material can include a Group III-V material. In one particular instance, the film 306 can include a nitride material. In another example, the film 306 can include gallium, aluminum, indium and a combination thereof. Still, in one particular embodiment, the film 306 can comprise aluminum nitride, and more particularly, may consist essentially of aluminum nitride.

Accordingly, in an exemplary structure, the buffer layer 303 can be formed such that the film 304 includes silicon and is directly contacting a major surface of the substrate 301. Furthermore, the film 306 can directly contact a surface of the film 304 and include a Group III-V material.

After forming a buffer layer at step 103, the process can continue at step 105 by forming a thick epitaxial layer 305 overlying the buffer layer 303 as illustrated in the embodiment of FIG. 3. In particular, the thick epitaxial layer 305 can be formed such it is overlying a surface of the buffer layer 303, and more particularly, the thick epitaxial layer 305 can be in direct contact with the film 306 of the buffer layer 303.

According to an embodiment, upon suitably forming a buffer layer 303, the substrate 301 and buffer layer 303 may be placed within a reaction chamber to conduct an extended growth process carried out in a single chamber, without removing the work piece (e.g., semi conductive substrate) wherein a layer semiconductor material is formed to great thicknesses. In accordance with the embodiment, the extended growth process can utilize an epitaxial growth process, and more particularly a hydride vapor phase epitaxy (HVPE) process.

Particular methods of forming the thick epitaxial layer 305 can be undertaken. For example, the extended epitaxial growth process can be conducted in various growth modes. For example, in one embodiment, the thick epitaxial layer 305 is initially formed as an epitaxial layer grown in a 3-dimensional (3D) growth mode. A 3D growth mode can include the simultaneous growth of the thick epitaxial layer 305 material along multiple crystallographic directions. In such instances, formation of the thick epitaxial layer 305 in a 3D growth process can include spontaneous formation of island features on the buffer layer 303. The spontaneously formed island features can be randomly positioned on the buffer layer 303, defining various mesas having multiple facets and valleys between the mesas.

Alternatively, or additionally, formation of the thick epitaxial layer 305 can include epitaxial growth in a 2-dimensional (2D) growth mode. A 2D growth mode is characterized by preferential growth of the material in one crystallographic direction and limited growth of the crystalline material along other crystallographic directions. For example, in one embodiment, formation of a thick epitaxial layer 305 comprising GaN in a 2D growth mode includes preferential growth of the GaN in the c-plane (0001), such that vertical growth of the base layer material is stabilized over lateral growth.

Still, formation of the thick epitaxial layer 305 can incorporate a combination of 3D and 2D growth modes. For example, the thick epitaxial layer 305 may be initially formed in a 3D growth mode, wherein island features are spontaneously formed on the buffer layer 303 as a non-continuous layer of material. Following the 3D growth mode, growth parameters can be altered to change to a 2D growth mode, wherein vertical growth is accelerated over lateral growth. Upon switching from a 3D growth mode to a 2D growth mode, the spontaneously formed islands may coalesce into a continuous layer of uniform thickness. Combining 3D and 2D growth modes can facilitate formation of a base layer having desirable characteristics, such as a particular dislocation density.

In accordance with an embodiment, the thick epitaxial layer 305 including the Group III-V material can have an average thickness that is significantly greater than epitaxial layers formed in conventional epitaxial processes. Typical epitaxial processes form semiconductive layers of less than about 2 mm and usually GaN growth rate decreases significantly after hours of continuous growth due to the change in the Ga level of an internal Ga reservoir with a finite volume. By contrast, the systems of the embodiments herein facilitate the formation of thick epitaxial layers having an average thickness (t) of greater than about 4 mm, such as at least about 5 mm, at least about 6 mm, at least about 8 mm, or even at least about 10 mm because the external reservoir can maintain a constant Ga level in the internal reservoir for extended durations (e.g., days) due to a combination of features, including but not limited to, the surface areas ratio between the first and second chambers and recharging capabilities without interruption of the growth process. The thick epitaxial layer 305 can be formed with sufficient thickness (e.g., an average thickness greater than 5 mm) such that it may be sectioned (shown as dotted lines in FIG. 3) into multiple, individual, free-standing crystalline semiconductor wafers. As such, the thick epitaxial layer 305 may be considered a boule.

The embodiments herein represent a departure from the state-of-the-art. While certain semiconductor materials have been growth using a bubbler system, typical systems used in the formation of GaN are limited and are not developed for extended growth operations and have not addressed the challenges associated with developing a system enabling such operations release layers during a continuous growth process. The present application discloses a system used in the formation of semiconductor crystalline materials and enabling extended epitaxial growth operations through the combination of features including, but not limited to, first and second chambers, particular materials for forming the components, arrangement and attachment of conduits relative to each other and relative to the growth chambers, bubblers having particular features, and the like. Moreover, the combination of features is formed to enable safe containment of a liquid metal without significant contamination and under proper conditions to maintain the phase of the metal material.

In the foregoing, reference to specific embodiments and the connections of certain components is illustrative. It will be appreciated that reference to components as being coupled or connected is intended to disclose either direct connection between said components or indirect connection through one or more intervening components as will be appreciated to carry out the methods as discussed herein. As such, the above-disclosed subject matter is to be considered illustrative, and not restrictive, and the appended claims are intended to cover all such modifications, enhancements, and other embodiments, which fall within the true scope of the present invention. Thus, to the maximum extent allowed by law, the scope of the present invention is to be determined by the broadest permissible interpretation of the following claims and their equivalents, and shall not be restricted or limited by the foregoing detailed description.

The Abstract of the Disclosure is provided to comply with Patent Law and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all features of any of the disclosed embodiments. Thus, the following claims are incorporated into the Detailed Description, with each claim standing on its own as defining separately claimed subject matter.

1. A system used in the formation of a semiconductor crystalline material comprising:
a first chamber configured to contain a liquid metal;
a second chamber in fluid communication with the first chamber, the second chamber having a greater surface area than a surface area of the first reservoir chamber; and
a vapor delivery conduit coupled to the first chamber configured to deliver a vapor phase reactant material into the first chamber to react with the liquid metal and form a metal halide vapor phase product.

2. The system of claim 1, further comprising an exit coupled to the first chamber configured to remove the metal halide vapor phase product from the first chamber.

3. The system of claim 2, wherein the exit conduit is coupled to a growth chamber.

4. The system of claim 1, wherein the second chamber comprises a volume greater than a volume of the first reservoir, wherein the second chamber comprises a volume at least 10 times greater than a volume of the first reservoir chamber volume.

5. The system of claim 1, wherein the second chamber comprises a surface area at least 2 times greater than a surface area of the first reservoir chamber volume.

6-8. (canceled)

9. The system of claim 1, wherein the vapor delivery conduit is a blower positioned in an upper half of the first chamber with respect to a height of the first chamber.

10. The system of claim 9, wherein the blower is configured to deliver the vapor phase reactant material to an upper surface of the liquid metal within the first chamber.

11. The system of claim 1, wherein the vapor delivery conduit is a bubbler.

12-14. (canceled)

15. The system of claim 1, wherein the first chamber and the second chamber are coupled via a reservoir conduit.

16. The system of claim 15, wherein the reservoir conduit is connected at the first chamber at a lower half with respect to a height of the first chamber.

17. The system of claim 15, wherein the reservoir conduit is connected at the second chamber at a lower half with respect to a height of the second chamber.

18. The system of claim 1, wherein the first chamber is contained within a growth chamber.

19. The system of claim 1, wherein the second chamber is external to a growth chamber.

20. The system of claim 1, wherein a portion of the vapor delivery conduit is external to a growth chamber.

21-22. (canceled)

23. The system of claim 1, wherein the second chamber is configured to replenish the liquid metal material within the first chamber as the liquid metal material within the first chamber reacts with the vapor phase reactant material.

24-29. (canceled)

30. The system of claim 1, wherein the metal halide vapor phase product is configured for use in an epitaxial growth process to form a Group III-V nitride semiconductor material.

31. The system of claim 30, wherein the metal halide vapor phase product is configured for use in an epitaxial growth process to form a boule of Group III-V nitride semiconductor material having a thickness of greater than about 4 mm.

32. The system of claim 31, wherein the boule of Group III-V nitride semiconductor material has a thickness of greater than about 1 cm.

33. A system used in the formation of a semiconductor crystalline material comprising:
a first chamber configured to contain a liquid metal;
a second chamber in fluid communication with the first chamber, the second chamber having a greater surface area than a surface area of the first chamber; and
a vapor delivery conduit comprising a bubbler at least partially contained within the first chamber and submerged within the liquid metal configured to deliver a vapor phase reactant material into the liquid metal and form a metal halide vapor phase product.

34-47. (canceled)

48. The system of claim 33, wherein the second chamber is configured to replenish the liquid metal material within the first chamber as the liquid metal material within the first chamber reacts with the vapor phase reactant material.

49-54. (canceled)

55. The system of claim 33, wherein the metal halide vapor phase product is configured for use in an epitaxial growth process to form a boule of Group III-V nitride semiconductor material having a thickness of greater than about 4 mm.

56. A system used in the formation of a semiconductor crystalline material comprising:
a first chamber comprising a temperature sufficient to maintain liquid gallium;
a second chamber in fluid communication with the first chamber and configured to contain a greater volume of liquid metal than a volume of liquid metal within the first chamber and replenish the liquid metal within the first chamber during operation, wherein the second chamber is external to a growth chamber; and
a vapor delivery conduit comprising a bubbler at least partially contained within the first chamber and submerged within the liquid metal configured to deliver a vapor phase reactant material into the liquid metal and form a metal halide vapor phase product.
